(19) United States
(12) Patent Application Publication
(10) Pub. No.: US 2016/0190377 A1
(43) Pub. Date: Jun. 30, 2016

(54) A HIGH EFFICIENCY STACKED SOLAR CELL

(71) Applicant: NEWSOUTH INNOVATIONS PTY LIMITED, Sydney, New South Wales (AU)

(72) Inventor: Martin Andrew Green, New South Wales (AU)

(73) Assignee: NEWSOUTH INNOVATIONS PTY LIMITED, Sydney, New South Wales (AU)

(21) Appl. No.: 14/910,831

(22) PCT Filed: Aug. 6, 2014
(86) PCT No.: PCT/AU2014/000787

§ 371 Date: Feb. 8, 2016

(30) Foreign Application Priority Data
Aug. 6, 2013 (AU) 2013902948

(51) Int. Cl. H01L 31/0687; H01L 31/028; H01L 31/032; H01L 31/18

(52) U.S. Cl. CPC H01L 31/0687; H01L 31/1804; H01L 31/18; H01L 31/028; H01L 31/032

(57) ABSTRACT

The present disclosure provides a photovoltaic device that has a photon receiving surface and a first single homojunction silicon solar cell. The first single homojunction silicon solar cell comprises two doped silicon portions with opposite polarities and has a first bandgap. The photovoltaic device further comprises a second solar cell structure that has an absorber material with a Perovskite structure and has a second bandgap that is larger than the first bandgap. The photovoltaic device is arranged such that each of the first and second solar cells absorb a portion of the photons that are received by the photon receiving surface.

### FIELD OF THE INVENTION

The present invention generally relates to photovoltaic devices comprising multiple stacked solar cells.

### BACKGROUND OF THE INVENTION

The cost of silicon solar cells has decreased dramatically in the past few years and it is to be expected that silicon technology will remain firmly entrenched over the coming decade as the dominant photovoltaic technology. Improvement of the conversion efficiency of such solar cells will continue to be a key factor. However, single junction silicon based solar cells have a theoretical efficiency limit of 29% and record efficiencies of approximately 25% have been demonstrated for laboratory-based solar cells.

To further increase the efficiency of silicon based solar cells, the most promising approach is to stack cells of different materials on top of a silicon-based solar cell. By stacking a further solar cell on a silicon-based solar cell, the theoretically possible performance increases from 29% to 42.5%. By stacking two further solar cells on the silicon-based cell, the theoretically possible performance increases to 47.5%.

The challenge has been to fabricate high performing photovoltaic materials of this type at a reasonable cost.

### SUMMARY OF THE INVENTION

In accordance with a first aspect, the present invention provides a photovoltaic device comprising:
a photon receiving surface;
a first single homojunction silicon solar cell comprising two doped silicon portions with opposite polarities and having a first bandgap; and
a second solar cell structure comprising an absorber material that has a Perovskite structure and has a second bandgap that is larger than the first bandgap;
wherein the photovoltaic device is arranged such that each of the first and second solar cells absorb a portion of the photons that are received by the photon receiving surface.

Embodiments of the present invention combine the advantages of silicon solar cells with those of a Perovskite cell and provide stacked cells that may have an increased conversion efficiency compared with single silicon-based cells.

The photovoltaic device may be arranged such that also a portion of photons that have an energy that approximates that of the second bandgap or even exceeds an energy of the second band gap penetrate through a portion of the at least one second solar cell structure and are absorbed by the first solar cell structure.

The second solar cell may be one of a plurality of second solar cells that are configured in a stack and each second solar cell of the stack may comprise an absorber material that has a Perovskite structure and a bandgap that is larger than the bandgap of the second solar cell positioned below in the stack.

In some embodiments, the first silicon solar cell has a junction region that comprises dopant atoms associated with a first polarity and are diffused into silicon material of a second polarity.

In alternative embodiments, the first silicon solar cell has a junction region having dopant atoms associated with a first polarity implanted into silicon material of a second polarity.

In further alternative embodiments, the first silicon solar cell comprises a silicon layer of a first polarity grown onto a surface portion of a silicon layer of a second polarity. The silicon layer of a first polarity may be an epitaxial silicon layer.

In accordance with a second aspect, the present invention provides a photovoltaic device comprising:
a photon receiving surface;
a first silicon solar cell comprising two doped silicon portions with opposite polarities and having a first bandgap;
a second solar cell structure comprising an absorber material that has a Perovskite structure and having a second bandgap that is larger than the first bandgap; and
at least one third solar cell structure comprising a material that has a Perovskite structure and having a third bandgap that is larger than the second bandgap; and
wherein the photovoltaic device is arranged such that each of the first, second and at least one third solar cell structures absorbs a portion of the photons that are received by the photon receiving surface.

The following relates to optional features of the invention in accordance with the either the first aspect of the present invention or the second aspect of the present invention.

The second solar cell structure may be disposed over a surface portion of the first solar cell. This surface portion may be a textured surface portion.

In some embodiments, the region adjacent the surface portion of the first solar cell has a sheet resistivity between 5 and 300 Ohm/square along the planar direction of the surface portion. In some embodiments this resistivity may be between 10 and 30 Ohm/square.

In embodiments, the photovoltaic device comprises an interconnecting region disposed in proximity to the surface portion of the first solar cell and arranged to facilitate the transport of charge carriers from one the solar cell to another. The interconnecting region may include the surface portion of the first solar cell.

In some embodiments, the interconnecting region comprises a transparent conductive oxide layer or a doped semiconductor layer which has a higher bandgap than the first bandgap. The interconnecting region may comprise a tunneling junction. Further, the interconnecting region may comprise a region with a high concentration of electrically active defects such as a defect junction between the first and the second solar cell. In embodiments, the interconnecting region also includes a portion of the first or second solar cell.

In some embodiments, the first solar cell of the photovoltaic device is a thin film silicon solar cell. In alternative embodiments, the first solar cell is a wafer-based mono-crystalline silicon solar cell and may be configured similarly to a Passivated Emitter and Rear Locally-diffused (PERL) silicon solar cell. The first solar cell may also be a multi-crystalline silicon solar cell or a peeled silicon wafer solar cell.

Typically, the second solar cell structure is a thin film solar cell. The second solar cell may be a solid state solar cell and may comprises a hole-transport material which facilitates the transport of holes from the second solar cell structure to the first solar cell or a contact structure. Further, the second solar cell structure may comprise a nano- or micro-structured polycrystalline material, a porous material or a mesoporous material.

In some embodiments, the absorber material of the second solar cell is a self-assembled material and may comprise an inorganic-organic compound. The light absorbing layer may comprise any one or a combination of MAPb(I_{(1-X)}Br_{X})₃, MAPb_{(1-X)}Sn_{X}I₃, Al₂O₃, SrTiO₃ and TiO₂. The MAPb (I_{1-X})Br_{X})₃ material may comprise CH₃NH₃Pb(I_{(1-X)}Br_{X})₃, and MAPb_{(1-X)}Sn_{X}I₃ comprises CH₃NH₃Pb_{(1-X)}Sn_{X}I₃, where MA stands for the methyl ammonium cation. Other organic cations such as the ethyl ammonium or formamidinium may also be used.

Typically, the bandgaps of one or more solar cells can be tuned by controlling the amount of Br or Sn in the absorbing layers during the manufacturing of the photovoltaic device, or the organic cation employed.

In some embodiments, the photovoltaic device is arranged such that charge carriers are transferred from a p-doped region of the first solar cell to the second solar cell structure. In alternative embodiments the photovoltaic device is arranged such that charge carriers are transferred from an n-doped region of the first solar cell to the second solar cell structure.

In accordance with a third aspect, the present invention provides a method of manufacturing a photovoltaic device comprising the steps of:
providing a substrate;
forming a first single homojunction silicon solar cell using the substrate, the first solar cell comprising two doped silicon portions with opposite polarities and having a first bandgap; and
depositing at least one second solar cell structure over the first solar cell structure, the at least one second solar cell structure comprising an absorber material that has a Perovskite structure and having a second bandgap that is larger than the first bandgap.

In some embodiments, the substrate is a silicon substrate of the first solar cell has a p-n junction. The first solar cell may be a wafer based mono-crystalline or multi-crystalline silicon solar cell. Alternatively, the first solar cell may be a thin film silicon solar cell.

The method may also comprise the step of forming an interconnecting region, between the first and the second solar cell, arranged to facilitate the transport of charge carriers from one solar cell to another.

The step of forming the interconnecting region may comprise the step of processing a surface between the first and the second solar cell in manner such that the carrier recombination velocity at the surface is increased. Further, the step of forming the interconnecting region may comprise the step of forming a tunnel junction within a surface portion of the first solar cell.

The step of depositing at least one second solar cell structure over the first solar cell may comprises a self-assembling deposition step, a spin coating step, a CVD step, or a PVD step.

### BRIEF DESCRIPTION OF THE DRAWINGS

Features and advantages of the present invention will become apparent from the following description of embodiments thereof, by way of example only, with reference to the accompanying drawings in which:

FIGS. 1 and 2 are schematic representations of tandem solar cells devices in accordance with embodiments of the present invention;

FIG. 3 is a flow diagram outlining the basic steps required to realise a tandem solar cell in accordance with embodiments of the present invention;

FIG. 4 is an illustration of a tandem solar cell consisting of a high efficiency silicon solar cell and a thin film Perovskite based solar cell in accordance with an embodiment of the present invention;

FIG. 5 is a schematic representation of a triple cell photovoltaic device in accordance with embodiments of the present invention;

FIG. 6 is a flow diagram outlining the basic steps required to realise a multiple cell photovoltaic device in accordance with embodiments of the present invention.

### DETAILED DESCRIPTION OF EMBODIMENTS

Embodiments of the present invention relate to high efficiency photovoltaic devices consisting of a series of solar cells stacked on top of each other. In particular, advantageous embodiments of the invention are related to a photovoltaic device consisting of a one of more thin films solar cells that include absorber materials with a Perovskite structure and are stacked on top of silicon single junction solar cell. In one embodiment, the device is configured as a tandem solar cell with a single homojunction silicon bottom cell and a thin film solid state Perovskite-based top cell. In these embodiments, the single homojunction cell comprises a silicon p-n junction which may be realised, for example, by diffusion of n-type dopants in a p-type silicon substrate or vice versa. Alternatively, the p-n junction may be realised using ion-implantation or epitaxy.

The single homojunction silicon bottom cell may be a single-crystalline cell realised on a crystalline silicon wafer. This cell could also be a multi-crystalline cell or, alternatively, a thin film silicon solar cell deposited, for example, on a glass substrate.

Solar cells with efficiencies above 15% can be fabricated using inorganic-organic Perovskite materials with relatively inexpensive techniques, such as liquid phase, physical or chemical vapour deposition, evaporation techniques, spin coating or self assembling techniques. These techniques are currently used or have previously been used in high volume silicon processing.

The combination of a silicon-based solar cell and Perovskite materials based solar cells provides the possibility to achieve high energy conversion efficiencies.

High quality Perovskite based solar cells, suitable to be stacked on a single junction silicon cell, can be formed on silicon material with an imperfect Perovskite crystal structure. A relevant parameter, which can be used to evaluate the suitability of the Perovskite based cell to be stacked on the silicon cell, is the external radiative efficiency (ERE). The ERE of commercial silicon cells is about 0.02% and the ERE of the best Perovskite cell fabricated to date is calculated to equal 0.06%. This value is adequate to achieve high conversion efficiencies when one or more Perovskite based solar cells are stacked on a silicon solar cell.

Materials with a Perovskite structure can be deposited onto rough surfaces including mesoporous materials. This means that Perovskite based solar cells can be deposited on silicon solar cells with a textured surface allowing to implement light trapping techniques.

Perovskites provide almost a perfect bandgap range to be used in a stack configuration with silicon solar cells. The ideal bandgap for a single cell stacked on silicon is 1.7 eV. The ideal bandgaps for two cells stacked on a silicon cell are 1.5 eV and 2.0 eV. However, if the ERE of the stacked cells is comparable to or better than that of silicon, high performance can also be obtained for cells with lower bandgaps, provided that the cells are designed to be partially transparent to light of photon energy above their bandgap.

Advantageous features of embodiment of the present invention are provided by the high integrated current density of Perovskite based solar cells at the ‘blue end’ of the solar spectrum. This integrated current density is higher than the current density of a silicon solar cell, an additional advantage when combined with the high voltage output for the stacked silicon cell-Perovskite cell configuration. The high-voltage, low current operation of this configuration allows reducing the amount of metal required to contact the photovoltaic device. Metallisation costs are rapidly becoming one of the major material costs in cell processing. The amount of metal needed is roughly proportional to the operating current density of the cell, with this reducing from circa 35 mA/cm² for a standard cell to circa 20 mA/cm² for a single Perovskite based cell stacked on silicon and approximately 14 mA/cm² for two stacked cells.

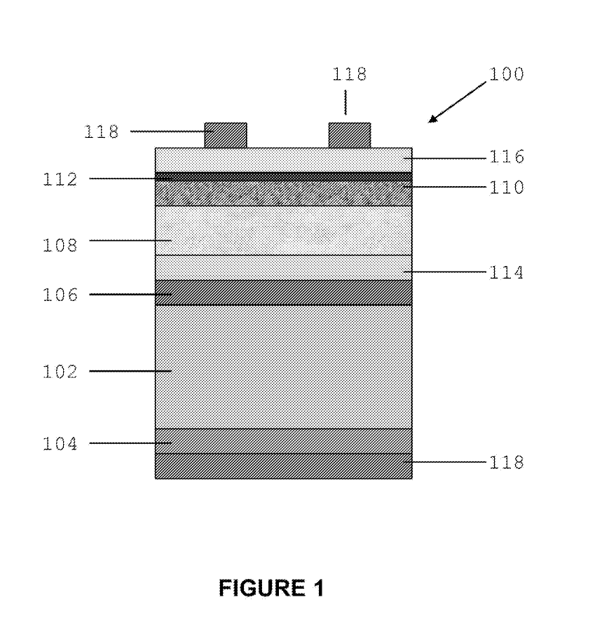

Referring now to FIG. 1, there is shown a schematic representation of a tandem solar cell device 100 in accordance with an embodiment of the present invention. The tandem solar cell consists of a silicon based bottom cell and a Perovskite material based top cell. Additional layers are used to improve charge carrier conduction between the bottom cell and the top cell and to aid the extraction of charge carriers from the device. In particular, the silicon bottom cell is realised by using a p-type silicon wafer 102, as in the majority of current commercial silicon based solar cells. A highly doped p-type area 104 may be realised at the back surface of the silicon wafer 102 to improve current extraction and decrease carriers surface recombination velocity. The p-n junction of the bottom cell is realised by introducing n-type dopants into the p-type silicon wafer 102, for example by diffusion, and creating an n-type layer 106. In FIG. 1 all the different layers are shown as flat layer for simplicity of illustration. However, one or more layers of the silicon bottom cell may be textured to improve optical and/or electrical properties of the solar cell. The surface of the first solar cell in proximity to the second solar cell may be textured, in which case, the top thin film solar cell follows the morphology of the textured surface.

The top cell is a thin film solar cell based on a Perovskite structured absorber layer 108. In this embodiment, the Perovskite layer 108 has a thickness of less than one micron and an optical bandgap (absorption threshold) of 1.5 eV or higher. In some embodiments of the invention, the Perovskite layer 108 is realised using the Perovskite methyl ammonium triiodide plumbate, tribromide, triiodide stannate or other halogen, organic cation and group IV elemental combinations.

Depending on the number of cells utilised on top of the silicon solar cell, Perovskite absorber materials with different bandgaps may be required. The bandgap of the Perovskite materials can be varied, for example, by mixing methyl ammonium triiodide plumbate with the tribromide MAPb(I_{(1-X)}Br_{X})₃ or CH₃NH₃Pb(I_{(1-X)}Br_{X})₃ or triiodide stannate MAPb_{(1-X)}Sn_{X}I₃ or CH₃NH₃Pb_{(1-X)}Sn_{X}I₃.

By mixing methyl ammonium triiodide plumbate with the tribromide, the bandgap can be varied between 1.6 eV and circa 2.3 eV. The triiodide stannate is reported to have bandgap about 0.1 eV or more lower than the plumbate, placing it in the range 1.2 eV to 1.6 eV. The Perovskite methyl ammonium triiodide plumbate (CH₃NH₃PbI₃) has an effective bandgap in the range of 1.6 eV. Other halogen, organic cation and group IV elemental combinations are likely to result in additional flexibility in selecting the bandgap.

A Perovskite scaffolding layer 110 can improve the morphology uniformity of the Perovskite absorbing layer. The Perovskite scaffolding layer 110 is generally realised using a metal oxide and in some instances may comprise a mixture of aluminium oxide (Al₂O₃) or other particles with Perovskite. The electron selective contact layer 112 may comprise TiO₂ and allows extraction of electrons from the device towards the conductive layer 116. In some implementations of the invention, the Perovskite scaffolding layer 110 and the electron selective contact layer 112 may be replaced with alternative electron conductive layers. The function of the conductive layer 116 is to create a low resistivity path for current extraction to the contacts 118. In embodiments of the invention, the layer 116 is realised by using a transparent conductive oxide (TCO) or doped high bandgap semiconductor layer.

A hole transportation layer 114 based on a hole transportation medium is deposited between the bottom silicon cell and the top Perovskite based cell to provide low resistance contact to the doped top layer 106 of the underlying silicon cell as well as transporting holes between the layer 106 and the Perovskite 108.

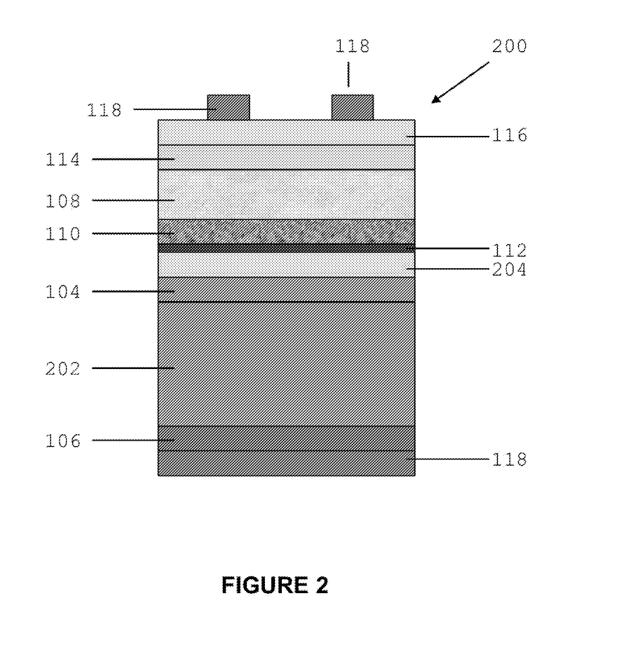

Referring now to FIG. 2, there is shown a schematic representation of tandem solar cell device 200 in accordance with an embodiment of the present invention. The tandem solar cell 200 has a similar configuration to the tandem solar cell 100 of FIG. 1, with a bottom silicon solar cell and a Perovskite material based top cell. However, the polarity of the cells in the tandem device 200 of FIG. 2 is inverted. The silicon bottom cell is realised by using an n-type silicon wafer 202. A highly doped n-type area 106 is realised at the back surface of the silicon wafer 202 to improve current extraction and decrease carriers surface recombination velocity. The bottom cell p-n junction is realised by introducing p-type dopants into the n-type silicon wafer 202 and creating a p-type layer 104. The top Perovskite based cell is a thin film solar cell with similar properties to the top cell of the device described in the embodiment of FIG. 1. In this embodiment, however, the electron selective contact layer 112 and the Perovskite scaffolding layer 110 are positioned on the silicon cell side of the top Perovskite cell structure, whereas the hole transportation layer 114 is positioned on the contacts side of the top cell. The inversion of the electron selective contact layer 112 and the hole transportation layer 114 equates to an inversion of polarity of the top cell. In some cases the Perovskite scaffolding layer 110 and the electron selective contact layer 112 may be replaced with alternative electron conductive layers.

The bottom and the top solar cells of the photovoltaic devices of FIGS. 1 and 2 are connected in series and, during operation share the same current. The interconnecting region between the first and the second solar cells is typically arranged to facilitate the transport of charge carriers from one the solar cell to another. This interconnecting region can implement the electrical interconnection of the solar cells and in different embodiments is disposed entirely in the first solar cell, across the first and the second solar cell and may comprise one or more layers of the tandem structure. Typically the interconnecting region includes at least a portion of the top surface of the first solar cell.

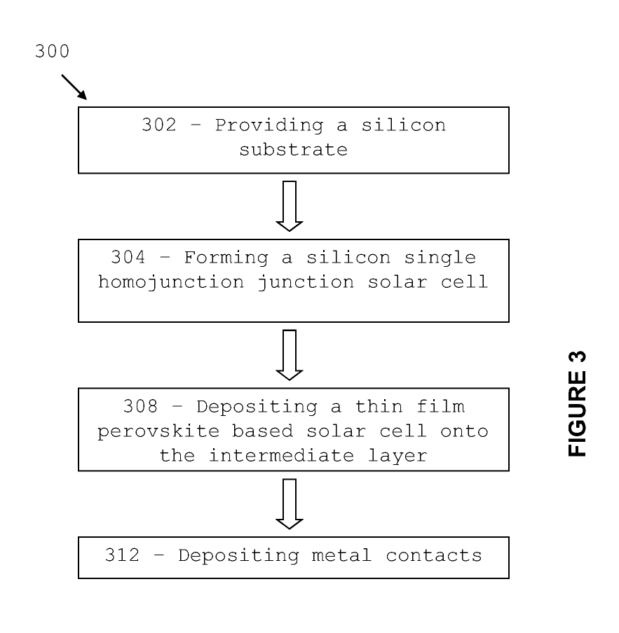

For example, in the structures of FIG. 2 the interconnection region comprises an intermediate layer 204. The intermediate layer 204 is deposited between the bottom silicon cell and the top Perovskite based cell to facilitate carrier transport between the two cells. This layer is generally a transparent conductive oxide, such as fluorine doped tin oxide (FTO). However, other types of material, including other conducting oxides or high bandgap doped semiconductors, can be used to implement the intermediate layer 204. In alternative embodiments, the Perovskite scaffolding layer 110 and the TiO₂ layer 112 may be eliminated or replaced with electron transporting layers. Referring now to FIG. 3, there is shown a flow diagram 300 outlining the basic steps required to realise a tandem solar cell in accordance with embodiments of the present invention. The first step 302 consists in providing a silicon substrate. A single homojunction silicon solar cell is formed using techniques known in the art (step 304). The substrate may then be transferred to deposition equipment to realise the necessary intermediate layers onto the silicon solar cell. Depending on the deposition technique used to realise the Perovskite material based solar cell, the substrate may be transferred to a further deposition tool to deposit the thin film Perovskite top cell (step 308). Transparent conductive layers may then be deposited before the metal contacting structure is realised (step 312).

The deposition of the Perovskite top cell (step 308) may be realised using various deposition techniques, such as liquid phase, physical or chemical vapour deposition, evaporation techniques, spin coating or self assembling techniques. In some embodiments, the Perovskite absorbing material is realised in a single step by depositing a Perovskite material on a mesoporous metal oxide film. In other embodiments the Perovskite absorbing material is realised in two steps by depositing one part of the Perovskite into the pores of the metal-oxide scaffold 110 and exposing the deposited area to a solution that contains the other component of the Perovskite. The chemical reaction that occurs when the two parts come into contact creates the light absorbing Perovskite material. This second method allows an improved control of the uniformity of the top cell.

In alternative embodiments, the Perovskite material 108 is deposited directly on the hole transporting medium 114 (step 308) and a scaffolding layer 110 may be added in a successive step on onto the Perovskite material 108. In these embodiments, the hole transporting medium 114 may be chemically or physically treated to improve its adhesion and/or electrical properties. The compact TiO₂ layer 112 may be subsequently deposited by a low temperature approach, such as sputtering or from chemical solution, given the low decomposition temperature of Perovskites materials (around 300 C). Successively, a transparent conductive oxide layer 116 is deposited (step 310) followed by contacts 118 (step 312).

In embodiments of the invention, the absorbing layer of the Perovskite based cells is an organic-inorganic compound, such as CH₃NH₃PbX₃, where X may be one of Cl, Br or I.

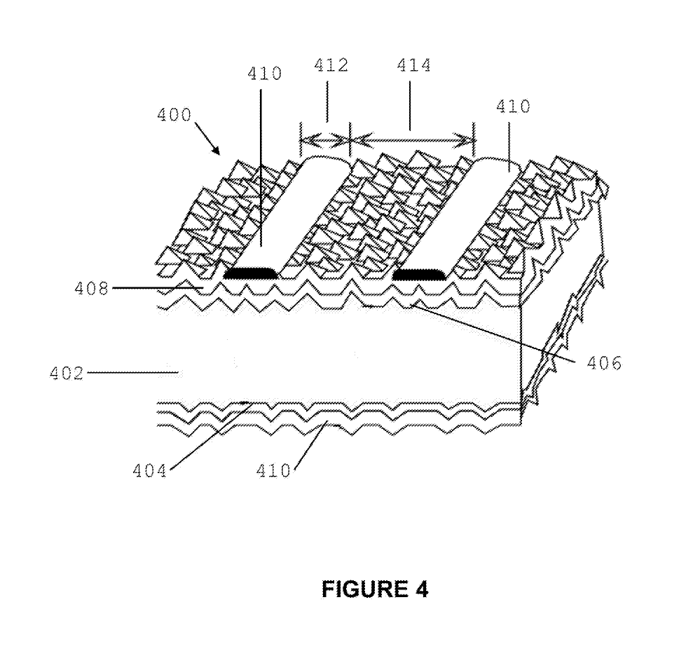

Referring now to FIG. 4, there is shown an illustration of a tandem solar cell 400 consisting of a high efficiency single junction silicon solar cell and a thin film Perovskite based solar cell in accordance with an embodiment of the present invention. The tandem cell 400 of FIG. 4 is configured as the device 100 of FIG. 1 or the device 200 shown in FIG. 2. The bottom silicon solar cell is a mono-crystalline or multi-crystalline silicon solar cell realised using a p-type silicon wafer 402. The bottom cell has a highly doped p-type area 404 at the back surface and the p-n junction is realised by introducing n-type dopants into the p-type silicon wafer 406. In some implementation of the invention, one or more surfaces of the mono-crystalline silicon solar cell are passivated to reduce recombination of minority carriers. Highly doped areas may be realised on the back surface of the bottom cell in correspondence of the back metallic contacts (not shown in FIG. 4) to decrease contact resistance and reduce carrier recombination. In addition, the device may be textured to improve light trapping. In a particular implementation of the photovoltaic device, the bottom silicon cell is configured similarly to a Passivated Emitter and Rear Locally-diffused (PERL) solar cell. The PERL cell is realised by the Photovoltaics Research Centre at the University of New South Wales, Australia, and currently holds the world efficiency record for a silicon single junction solar cell.

The top cell 408 is a thin film Perovskite based solar cell deposited on top of the silicon bottom cell. In some embodiments, intermediate layers are deposited between the bottom and the top cells. The bottom crystalline silicon solar cell may be textured to improve light trapping. The Perovskite top cell is deposited over the textured surface of the silicon bottom cell. The physical and electrical properties of the Perovskite top cell allow maintaining adequate cell performance even if the cell is deposited on a textured surface. The device 400 of FIG. 4 operates at lower currents and substantially higher voltages than a single silicon solar cell. This allows reducing the amount of metal required to contact the photovoltaic device. Metal contacts 410 with a lower width 412 and increased spacing 414 can be used to contact the device, reducing metallisation costs and shading losses. In addition, the good performance of the thin film perovskite top cell to short visible wavelengths allows relaxing the design requirements of the silicon bottom cell top surface, further simplifying the device fabrication process.

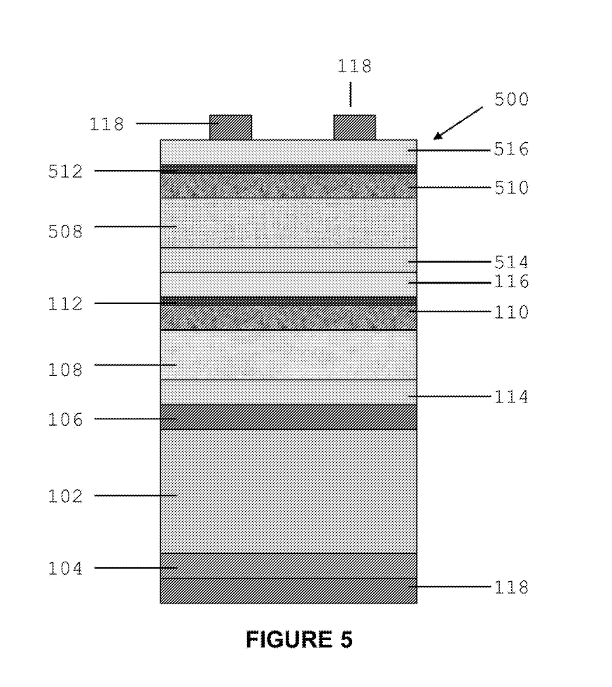

Referring now to FIG. 5, there is shown a schematic representation of a triple cell photovoltaic device 500 in accordance with embodiments of the present invention. The device 500 is configured in a similar manner to the device 100 of FIG. 1. The device 100 of FIG. 1 is substantially identical to the bottom silicon cell and the first Perovskite based cell of the device 500 of FIG. 5. However, the device 500 of FIG. 5 comprises a further thin film Perovskite based cell deposited on top of the middle cell. A further hole transportation layer 514 is deposited on the conductive layer 116. A thin film top Perovskite based solar cell is then deposited on the hole transportation layer 514. The absorbing material of the top cell has an optical bandgap higher than the optical bandgap of the middle cell. A further electron selective contact layer 512 is positioned on top of the stack and a conductive layer 516 is realised to create a low resistivity path for current extraction to the contacts 118.

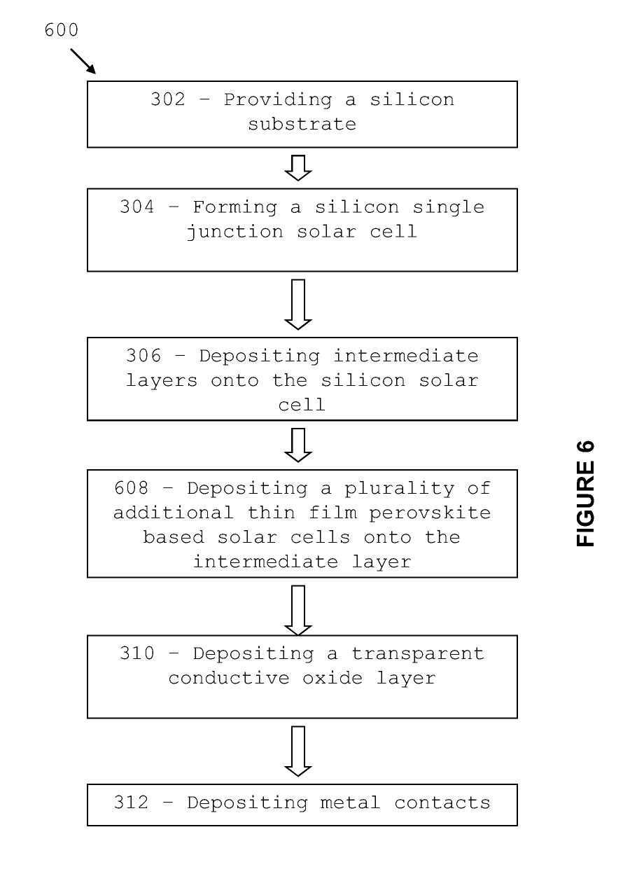

Referring now to FIG. 6, there is shown a flow diagram 600 outlining the basic steps required to realise a multiple cell photovoltaic device in accordance with embodiments of the present invention. The initial and final steps of the diagram 600 of FIG. 6 are substantially identical to the initial and final steps of the diagram 300 of FIG. 3. However, in the diagram 600 of FIG. 6, multiple thin films Perovskite based cells are deposited in series 608 before depositing the final conductive layer 310 and the contacting structures 312.

It will be appreciated by persons skilled in the art that numerous variations and/or modifications may be made to the invention as shown in the specific embodiments without departing from the spirit or scope of the invention as broadly described. The present embodiments are, therefore, to be considered in all respects as illustrative and not restrictive.

1. A photovoltaic device comprising:
a photon receiving surface;
a first single homojunction silicon solar cell comprising two doped silicon portions with opposite polarities and having a first bandgap; and
a second solar cell structure comprising an absorber material that has a Perovskite structure and having a second bandgap that is larger than the first bandgap;
wherein the photovoltaic device is arranged such that each of the first and second solar cells absorb a portion of the photons that are received by the photon receiving surface.

2. (canceled)

3. The photovoltaic device according to claim 1 wherein the first silicon solar cell has a junction region having dopant atoms associated with a first polarity and which are diffused into silicon material of a second polarity.

4-6. (canceled)

7. A photovoltaic device comprising:
a photon receiving surface;
a first single silicon solar cell comprising two doped silicon portions with opposite polarities and having a first bandgap;
a second solar cell structure comprising an absorber material that has a Perovskite structure and has a second bandgap that is larger than the first bandgap; and
at least one third solar cell structure comprising a material that has a Perovskite structure and having a third bandgap that is larger than the second bandgap; and
wherein the photovoltaic device is arranged such that each of the first, second and at least one third solar cell structures absorb a portion of the photons that are received by the photon receiving surface.

8-9. (canceled)

10. The photovoltaic device according to claim 1 further comprising an interconnecting region disposed in proximity to a portion of the first solar cell and arranged to facilitate the transport of charge carriers from one the solar cell to another.

11. The photovoltaic device according to claim 4 wherein the interconnecting region includes the portion of the first solar cell.

12. The photovoltaic device according to claim 4 wherein the interconnecting region comprises a transparent conductive oxide layer or a doped semiconductor layer with a higher bandgap than the first bandgap.

13. The photovoltaic device according to claim 4 wherein the portion of the first solar cell is a surface portion and has a sheet resistivity between 5 and 300 Ohm/square along the planar direction of the surface portion.

14. The photovoltaic device according to claim 7 wherein the surface portion has a resistivity between 10 and 30 Ohm/square along the planar direction of the surface portion.

15. (canceled)

16. The photovoltaic device according to claim 4 wherein the interconnecting region includes a portion of the second solar cell.

17. The photovoltaic device according to claim 4 wherein the interconnecting region comprises a region with a concentration of electrically active defects above 10¹⁸ cm⁻³.

18-19. (canceled)

20. The photovoltaic device according to claim 1 wherein the first solar cell is a mono-crystalline silicon solar cell configured as a Passivated Emitter and Rear Locally-diffused (PERL) silicon solar cell.

21. (canceled)

22. The photovoltaic device according to claim 1 wherein the second solar cell structure is a thin film solid state solar cell.

23-25. (canceled)

26. The photovoltaic device according to claim 1 wherein the absorber material of the second solar cell comprises a self-assembled inorganic-organic compound.

27. (canceled)

28. The photovoltaic device according to claim 13 wherein the light absorbing layer comprises any one or a combination of MAPb(I_{(1-X)}Br_{X})₃, MAPb_{(1-X)}Sn_{X}I₃, Al₂O₃, SrTiO₃ and TiO₂.

29. (canceled)

30. The photovoltaic device according to claim 14 wherein the bandgaps of one or more solar cells are tuned by controlling the amount of Br, Sn or the organic cation employed during the manufacturing of the photovoltaic device.

31-32. (canceled)

33. A method of manufacturing a photovoltaic device comprising the steps of:
providing a substrate;
forming a first single silicon homojunction solar cell using the substrate, the first solar cell comprising two doped silicon portions with opposite polarities and, having a first bandgap; and
depositing at least one second solar cell structure over the first solar cell structure, the at least one second solar cell structure comprising an absorber material that has a Perovskite structure and having a second bandgap that is larger than the first bandgap.

34. The method according to claim 16 wherein the substrate is a silicon substrate and the first solar cell has a p-n junction.

35-36. (canceled)

37. The method according to claim 16 further comprising the step of forming an interconnecting region between the first and the second solar cell arranged to facilitate the transport of charge carriers from one solar cell to another.

38. The method according to claim 18 wherein the step of forming the interconnecting region comprises the step of processing a surface between the first and the second solar cell in manner such that the carrier recombination velocity at the surface is increased.

39. (canceled)

40. The method according to claim 16 wherein the step of depositing at least one second solar cell structure over the first solar cell comprises a self-assembling deposition step, a spin coating step, a CVD step, or a PVD step.
